(19) United States
(12) Patent Application Publication
(10) Pub. No.: US 2024/0208361 A1
(43) Pub. Date: Jun. 27, 2024

(54) CROSS-COMPATIBLE BATTERY MODULES FOR MICROGRID SYSTEMS

(71) Applicant: ELECTRIC POWER SYSTEMS, INC., North Logan, UT (US)

(72) Inventors: MICHAEL ARMSTRONG, North Logan, UT (US); NATHAN MILLECAM, North Logan, UT (US); STEVEN HALL, North Logan, UT (US); RANDY DUNN, Orange, CA (US); KURT ROSE, North Logan, UT (US)

(73) Assignee: ELECTRIC POWER SYSTEMS, INC., North Logan, UT (US)

(21) Appl. No.: 18/420,307

(22) Filed: Jan. 23, 2024

Related U.S. Application Data
(63) Continuation of application No. PCT/US2022/038533, filed on Jul. 27, 2022.
(60) Provisional application No. 63/226,086, filed on Jul. 27, 2021.
(60) Provisional application No. 63/244,094, filed on Sep. 14, 2021.
(60) Provisional application No. 63/244,108, filed on Sep. 14, 2021.
(60) Provisional application No. 63/313,640, filed on Feb. 24, 2022.
(60) Provisional application No. 63/313,660, filed on Feb. 24, 2022.

(51) Int. Cl. B60L 58/16; B60L 53/53; B60L 53/57; B60L 53/66; B60L 58/18

(52) U.S. Cl. CPC B60L 58/16; B60L 53/53; B60L 53/57; B60L 53/66; B60L 58/18; B60L 2200/10

(57) ABSTRACT

A microgrid charging system may comprise: a battery system comprising a first plurality of battery modules; a battery management system including a controller in operable communication with the first plurality of battery modules, the controller operable to: receive battery data for each battery module in the first plurality of battery modules including at least one of a discharge frequency, shock and vibration data, battery capacity data; compare the battery data for each battery module in the first plurality of battery modules to an airworthiness standard; and determine whether each battery in the first plurality of battery modules meets the airworthiness standard. The first plurality of battery modules may be cross-compatible with a second plurality of battery modules in an aircraft battery system.

### CROSS-REFERENCE TO RELATED APPLICATIONS

This application is a continuation of PCT Application PCT/US2022/038533 filed Jul. 27, 2022 and titled “CROSS-COMPATIBLE BATTERY MODULES FOR MICROGRID SYSTEMS” (hereinafter the '533 Application). The '533 claims priority to, and the benefit of, Provisional Patent Application No. 63/226,086, filed Jul. 27, 2021 and titled “MOBILE MICROGRID ECOSYSTEM,” Provisional Patent Application No. 63/244,094, filed Sep. 14, 2021 and titled “MOBILE CHARGING SYSTEM WITH BI-DIRECTIONAL DC/DC CONVERTER,” Provisional Patent Application No. 63/244,108, filed Sep. 14, 2021 and titled “FLUID MANAGEMENT SYSTEM FOR MOBILE CHARGING SYSTEM,” Provisional Patent Application No. 63/313,640, filed Feb. 24, 2022 and titled “CROSS-COMPATIBLE BATTERY MODULES FOR MICROGRID SYSTEMS,” Provisional Patent Application No. 63/313,660, filed Feb. 24, 2022 and titled “COMMON BATTERY MODULES INTERFACES FOR MICROGRID SYSTEMS.” Each disclosure of the foregoing applications is incorporated herein by reference in its entireties, including but not limited to those portions that specifically appear hereinafter, but except for any subject matter disclaimers or disavowals, and except to the extent that the incorporated material is inconsistent with the express disclosure herein, in which case the language in this disclosure shall control.

### FIELD OF INVENTION

The present disclosure generally relates to apparatus, systems and methods for cross-compatible battery modules for multi-integration between charging battery systems and aircraft battery systems.

### BACKGROUND OF THE INVENTION

The subject matter discussed in the background section should not be assumed to be prior art merely as a result of its mention in the background section. Similarly, a problem mentioned in the background section or associated with the subject matter of the background section should not be assumed to have been previously recognized in the prior art. The subject matter in the background section merely represents different approaches, which in and of themselves may be inventions.

A battery module, for purposes of this disclosure, includes a plurality of electrically connected cell-brick assemblies. These cell-brick assemblies may, in turn, include a parallel, series, or combination of both, collection of electrochemical or electrostatic cells hereafter referred to collectively as “cells”, that can be charged electrically to provide a static potential for power or released electrical charge when needed. When cells are assembled into a battery module, the cells are often linked together through metal strips, straps, wires, bus bars, etc., that are welded, soldered, or otherwise fastened to each cell to link them together in the desired configuration.

A cell may be comprised of at least one positive electrode and at least one negative electrode. One common form of such a cell is the well-known secondary cells packaged in a cylindrical metal can or in a prismatic case. Examples of chemistry used in such secondary cells are lithium cobalt oxide, lithium manganese, lithium iron phosphate, nickel cadmium, nickel zinc, and nickel metal hydride. Such cells are mass produced, driven by an ever-increasing consumer market that demands low-cost rechargeable energy for portable electronics.

Custom battery solutions may be expensive for a respective customer. Custom battery solutions may include longer lead times due to the customization desired by the customer. Custom battery solutions may be engineering intensive to meet desired characteristics by a customer.

### SUMMARY OF THE INVENTION

A microgrid charging system is disclosed herein. The microgrid charging system may comprise: a battery system comprising a first plurality of battery modules; a battery management system including a controller in operable communication with the first plurality of battery modules, the controller operable to: receive battery data for each battery module in the first plurality of battery modules including at least one of a discharge frequency, shock and vibration data, battery capacity data; compare the battery data for each battery module in the first plurality of battery modules to an airworthiness standard; and determine whether each battery in the first plurality of battery modules meets the airworthiness standard.

In various embodiments, the microgrid charging system is configured to charge an aircraft battery system. The first plurality of battery modules may be cross-compatible with a second plurality of battery modules in the aircraft battery system. The microgrid charging system may further comprise an aircraft battery management system configured to operably couple to the aircraft battery management system of the microgrid charging system. The microgrid charging system may further comprise an aircraft battery monitoring system including a second controller operable to: receive, from the aircraft battery management system, the battery data for the second plurality of battery modules in the aircraft battery system in response to electrically coupling the aircraft battery management system to the battery system for charging; and determine whether any battery modules in the second plurality of battery modules no longer meets the airworthiness standard. The aircraft battery system may comprise a second plurality of battery modules, and a first battery module in the first plurality of battery modules is cross compatible with a second battery module in the second plurality of battery modules. The controller may further be operable to send an airworthiness status for each battery module in the first plurality of battery modules to a display device in response to coupling the battery management system to the onboard battery management system of the aircraft battery system.

A battery system is disclosed herein. The battery system may comprise: a microgrid charging system comprising a first plurality of battery modules, the microgrid charging system including a first discharge profile; an aircraft propulsion battery system comprising a second plurality of battery modules, the aircraft propulsion battery system including a second discharge profile, wherein: a first battery module in the first plurality of battery modules is identical to a second battery module in the second plurality of battery modules, the first battery module is adaptable to replace the second battery module, and the second battery module is adaptable to replace the first battery module.

In various embodiments, the second discharge profile may be at least five times greater than the first discharge profile. The battery system may further comprise an airworthiness commissioning module configured to determine an airworthiness status for each battery module in the first plurality of battery modules and the second plurality of battery modules. The first battery module in the first plurality of battery modules may be configured to replace the second battery module in the second plurality of battery modules in response to the first battery module having an airworthy airworthiness status and the second battery module having a non-airworthy airworthiness status, and wherein the second battery module in the second plurality of battery modules is configured to replace the first battery module in the first plurality of battery modules. The aircraft propulsion battery system may include an aircraft battery management system, and the aircraft battery management system may be configured to operably couple to an aircraft battery monitoring system of the microgrid charging system. The microgrid charging system may further comprise a microgrid monitoring system configured to monitor the first plurality of battery modules. The battery system may further comprise a vehicle battery monitoring system and a commissioning module, the vehicle battery monitoring system and the microgrid monitoring system in operable communication with the commissioning module.

A method is disclosed herein. The method may comprise: installing a first battery module in a microgrid charging system, the microgrid charging system configured to charge an aircraft propulsion battery system; determining a second battery module in the aircraft propulsion battery system no longer meets an airworthiness standard; determining the first battery module meets the airworthiness standard; and swapping the first battery module with the second battery module.

In various embodiments, the method may further comprise replacing the second battery module with the first battery module. Determining whether the first battery module meets the airworthiness standard may further comprise comparing at least one of: a battery capacity of the second battery module to a threshold battery capacity; a number of flight cycles of the second battery module to a threshold number of flight cycles; and a number of hours of the second battery module to a threshold number of hours.

A method is disclosed herein. The method may comprise: receiving, via a processor and through a microgrid monitoring system, an airworthiness status of each battery module in a first plurality of battery modules in a microgrid battery system; receiving, via the processor and through an aircraft battery monitoring system, the airworthiness status of each battery module in a second plurality of battery modules in an aircraft battery system; and determining, via the processor, a first battery module in the first plurality of battery modules to replace a second battery module in the second plurality of battery modules in response to the second battery module having a non-airworthy airworthiness status and the first battery module having an airworthy airworthiness status.

In various embodiments, the method may further comprise determining via the processor, the second battery module can replace the first battery module in the microgrid battery system. The airworthiness status may be determined by comparing at least one of: a battery capacity of the second battery module to a threshold battery capacity; a number of flight cycles of the second battery module to a threshold number of flight cycles; and a number of hours of the second battery module to a threshold number of hours.

### BRIEF DESCRIPTION OF THE DRAWINGS

A more complete understanding of the present disclosure may be derived by referring to the detailed description and claims when considered in connection with the Figures, wherein like reference numbers refer to similar elements throughout the Figures, and where:

FIG. 1 illustrates a perspective view of a battery system, in accordance with various embodiments;

FIG. 2 illustrates an interconnected battery module for use in a battery system, in accordance with various embodiments;

FIG. 3 illustrates a schematic view of a charging ecosystem, in accordance with various embodiments;

FIG. 4 illustrates a schematic view of a charging ecosystem, in accordance with various embodiments;

FIG. 5 illustrates a schematic view of a portion of a charging ecosystem, in accordance with various embodiments;

FIG. 6 illustrates a method for maintaining an aircraft battery system, in accordance with various embodiments; and

FIG. 7 illustrates a method for maintaining an aircraft battery system, in accordance with various embodiments.

### DETAILED DESCRIPTION

The following description is of various example embodiments only, and is not intended to limit the scope, applicability or configuration of the present disclosure in any way. Rather, the following description is intended to provide a convenient illustration for implementing various embodiments including the best mode. As will become apparent, various changes may be made in the function and arrangement of the elements described in these embodiments, without departing from the scope of the appended claims. For example, the steps recited in any of the method or process descriptions may be executed in any order and are not necessarily limited to the order presented. Moreover, many of the manufacturing functions or steps may be outsourced to or performed by one or more third parties. Furthermore, any reference to singular includes plural embodiments, and any reference to more than one component or step may include a singular embodiment or step. Also, any reference to attached, fixed, connected or the like may include permanent, removable, temporary, partial, full and/or any other possible attachment option. As used herein, the terms “coupled,” “coupling,” or any other variation thereof, are intended to cover a physical connection, an electrical connection, a magnetic connection, an optical connection, a communicative connection, a functional connection, and/or any other connection.

For the sake of brevity, conventional techniques for mechanical system construction, management, operation, measurement, optimization, and/or control, as well as conventional techniques for mechanical power transfer, modulation, control, and/or use, may not be described in detail herein. Furthermore, the connecting lines shown in various figures contained herein are intended to represent example functional relationships and/or physical couplings between various elements. It should be noted that many alternative or additional functional relationships or physical connections may be present in a modular structure.

A “battery array” as described herein refers to a plurality of batteries electrically coupled together. The term “array” is not meant to be limiting as to size, shape, configuration or the like. Any configuration of batteries coupled in series and/or parallel to form a battery system is within the scope of this disclosure.

Typically, battery systems are designed and configured for specific applications. In this regard, various applications have varying design considerations, such as capacity, discharge profiles, discharge frequency, structural capabilities, etc. Thus, various battery systems use various types of cells, configurations, or the like based on the specific design considerations for the battery system. In contrast, disclosed herein is a system with cross-compatible battery modules for two different and distinct systems. In this regard, in accordance with various embodiments, an aircraft battery system and a microgrid charging system may each be configured to utilize a plurality of battery modules, each battery module being cross-compatible with the other system.

In various embodiments, by having cross-compatible battery modules, the microgrid charging system may be configured to act, at least partially, as inventory for battery modules of the aircraft battery system. In this regard, if it is determined a battery module of the aircraft battery system is no longer airworthy, a battery module of the microgrid charging system that is airworthy may replace the non-airworthy battery module with relative ease.

In various embodiments, by having cross-compatible battery modules, the microgrid charging system may further be configured to act, at least partially, as a secondary life for battery modules of the aircraft battery system. In this regard, a battery that is no longer airworthy may still be utilized in the microgrid charging system in this secondary life application due to less stringent structural and capacity related criteria for the microgrid charging system relative to the aircraft battery system, in accordance with various embodiments.

In various embodiments, the microgrid charging system is configured to charge the aircraft battery system. In various embodiments, the aircraft battery system is configured to power an electrically powered aircraft (e.g., a drone, an autonomous aircraft, an electrically powered manned aircraft, etc.). In various embodiments, electrically powered aircraft includes any aircraft having at least a portion of power provided electrically (e.g., hybrid powered aircrafts or the like).

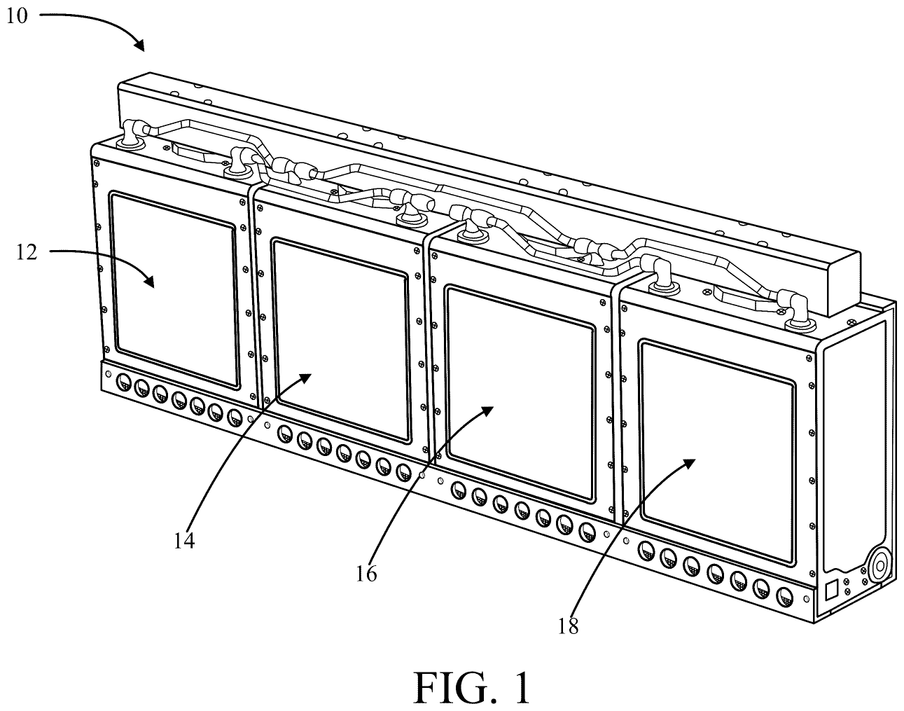

Referring now to FIG. 1, a perspective view of a portion of an interconnected battery system 10 is illustrated, in accordance with various embodiments. In various embodiments, the interconnected battery system 10 includes a plurality of interconnected battery modules (“ICBM” or “ICBMs”) (e.g., interconnected battery modules 12, 14, 16, 18). In various embodiments, each interconnected battery module (e.g., ICBMs 12, 14, 16, 18) includes a plurality of cells disposed therein. The plurality of cells may be cylindrical cells, prismatic cells, pouch cells, or any other cell. In various embodiments, the plurality of cells are a plurality of pouch cells.

In an example embodiment, an ICBM (e.g., ICBMs 12, 14, 16, 18) as disclosed herein may comprise a nominal voltage of approximately 39 volts, a capacity of approximately 58 ampere-hours, an energy output of approximately 2.3 kWh, or the like. Although an example ICBM may have these specifications, an interconnected battery module of any specification is within the scope of this disclosure. In an example embodiment, a 1,000 volt interconnected battery module system may be created by interconnecting one-hundred and thirty-six ICBMs in series as disclosed herein. In various embodiments, by having each ICBM isolated and discrete from the remaining ICBMs, a thermal runaway event may be limited to a single ICBM where the thermal runaway event occurs. In this regard, in accordance with various embodiments, an ICBM, as disclosed herein, may be configured to contain a thermal runaway event of a cell disposed in the ICBM without affecting any cell in any of the remaining ICBMs.

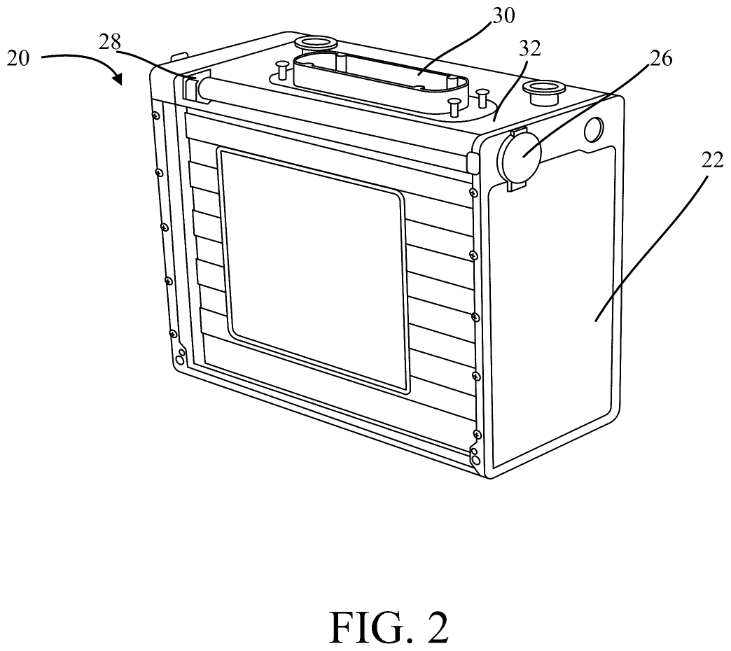

Referring now to FIG. 2, a perspective view of an ICBM 20 is illustrated with a translucent housing, in accordance with various embodiments. In various embodiments the ICBM 20 includes a housing 22 and a plurality of cells disposed in the housing 22. In various embodiments, the plurality of cells are a plurality of pouch cells. In various embodiments, the ICBM 20 includes a positive terminal 26 disposed on a first side of the housing 22 and a negative terminal 28 disposed on a second side of the housing 22.

In various embodiments, the positive terminal 26 is configured to electrically and physically couple to a negative terminal (e.g., negative terminal 28) of an adjacent ICBM in an interconnected battery system (e.g., interconnected battery system 10 from FIG. 1). Similarly, the negative terminal 28 is configured to electrically and physically couple to a positive terminal (e.g., positive terminal 26) of an adjacent ICBM in an interconnected battery system (e.g., interconnected battery system 10 from FIG. 1). In this regard, the ICBMs of interconnected battery system 10 may be configured for electrical and physical coupling in series electrically and may be configured with an additional component to create a parallel electrical connection, in accordance with various embodiments. The present disclosure is not limited in this regard. For example, the interconnected battery system may be configured to couple adjacent ICBMs in parallel as a default configuration instead of in series as a default configuration and still be within the scope of this disclosure.

In various embodiments, the housing 22 includes a vent port 30. In various embodiments, the vent port 30 is a fluid outlet in the plurality of fluid outlets in an interconnected battery system 10 from FIG. 1. In various embodiments, the vent port 30 is disposed on a top surface of the housing. The vent port 30 is in fluid communication with an internal cavity 32 of the housing 22. The plurality of cells are also disposed in the internal cavity 32. In this regard, any ejecta, gases, or foreign object debris (“FOD”) from a thermal runaway event may be configured to be expelled out the vent port 30 and into a common vent and out of the interconnected battery system (e.g., interconnected battery system 10 from FIG. 1).

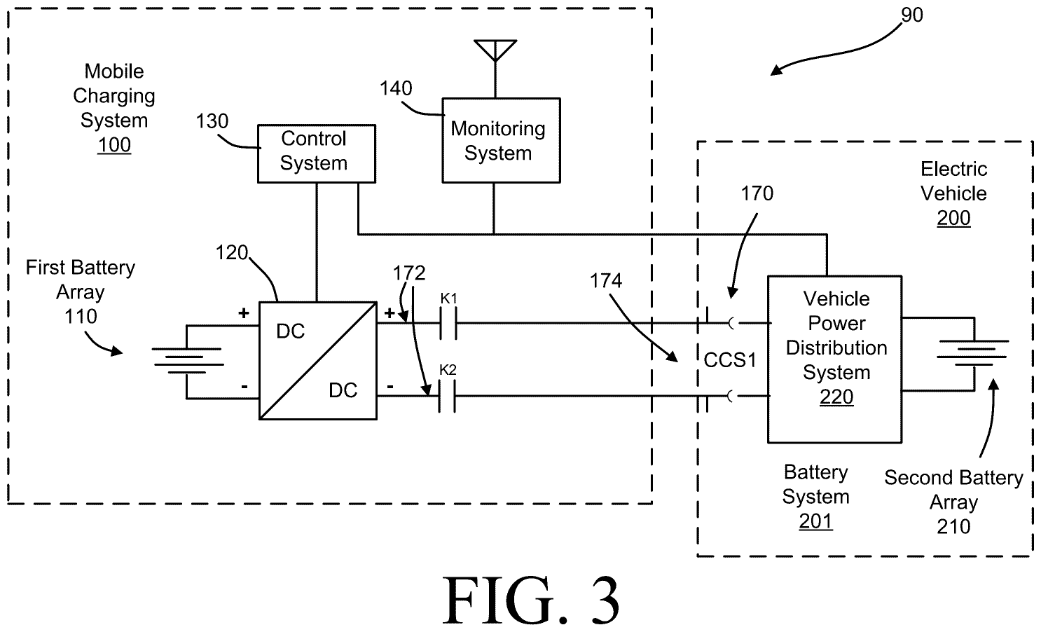

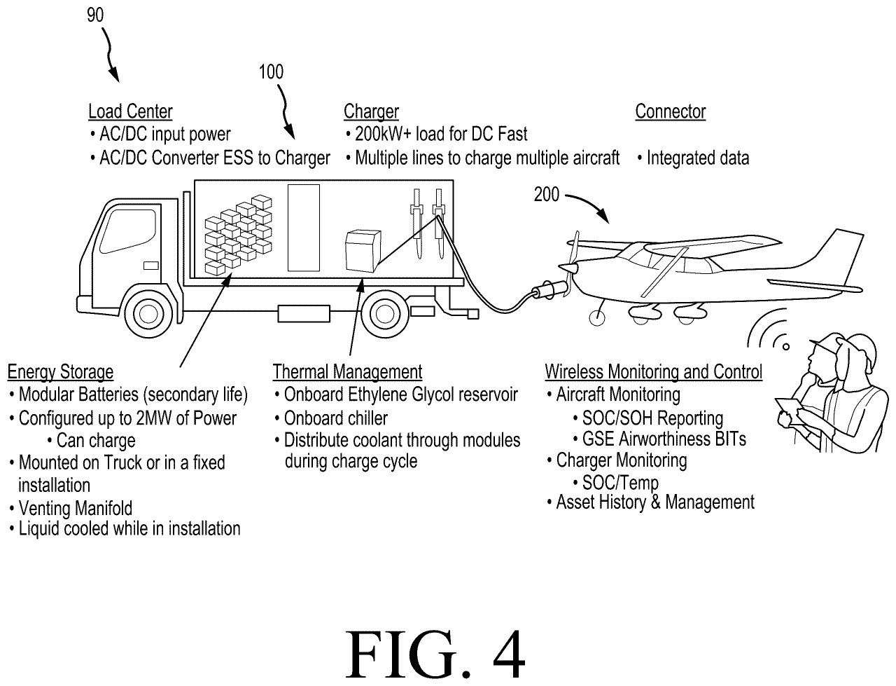

Referring now to FIGS. 3 and 4, a schematic view (FIG. 3) and a side view (FIG. 4) of an electric vehicle charging ecosystem 90 is illustrated, in accordance with various embodiments. The electric vehicle charging ecosystem 90 may be configured for charging an electric aircraft 200 (e.g., an electrically powered aircraft). The electric vehicle charging ecosystem 90 comprises a charging system 100 (e.g. a mobile microgrid charging system) and the electric aircraft 200 having an aircraft battery system 201.

In various embodiments, the charging system 100 is a mobile charging system. A “mobile charging system” as referred to herein refers to a battery system fixedly coupled to a wheeled vehicle (e.g., a truck, a lift, a van, a bus, a specialty vehicle or the like), a non-wheeled vehicle (e.g., vehicle with continuous track system, train system, etc.). In this regard, the charging system 100 may be configured to be transported from a fixed charging station (e.g., configured to charge the charging system 100) to a vehicle (e.g., electric aircraft 200) being charged via the charging system 100. Although described herein as a mobile charging system, the present disclosure is not limited in this regard. For example, a stationary, fixed, and/or non/moveable charging system is within the scope of this disclosure, in accordance with various embodiments.

The charging system 100 comprises a first battery array 110. Similarly, the electric aircraft 200 comprises the aircraft battery system 201 including a second battery array 210. In various embodiments, the first battery array 110 comprises a plurality of battery modules (e.g., ICBM 20 from FIG. 2). Similarly, the second battery array 210 comprises a plurality of battery modules (e.g., ICBM 20 from FIG. 2). In this regard, as described further herein, the battery modules of the electric aircraft 200 and the battery modules of the charging system are cross-compatible, in accordance with various embodiments. “Cross-compatible” as defined herein refers to being replaceable with, or swappable with (i.e., a battery module in the second battery array 210 could be swapped with a battery module in the first battery array 110 and vice versa). Although referred to herein as “battery arrays” any system of interconnected battery modules is within the scope of this disclosure. Thus, the term “array” is not a term limiting shape, or configuration, or the like for the battery systems disclosed herein, in accordance with various embodiments.

In various embodiments, the charging system 100 comprises the first battery array 110, a bi-directional direct current (DC)/DC converter 120, a control system 130, a monitoring system 140. In various embodiments, the first battery array 110 may be configured to charge the second battery array 210 of the electric aircraft 200. In various embodiments, the first battery array 110 may be configured to be charged via a fixed electrical grid (e.g., configured to receive AC/DC input power) or the like. In various embodiments, the bi-directional DC/DC converter 120 is in operable communication with the control system 130. In this regard, the control system 130 may be configured to control charging of the second battery array 210 by the first battery array 110 through the DC/DC converter 120. In various embodiments, the first battery array 110 may be mounted within a vehicle (e.g., a truck or the like as shown in FIG. 4). In various embodiments, the first battery array 110 may be a component of an energy storage system of the charging system 100.

In various embodiments, the electric vehicle charging ecosystem 90 comprises a combined charging system (CCS) 170 configured for high-power DC fast charging. Although illustrated as comprising a United States style combined charging system (“CCS1”) charging system, the charging system is not limited in this regard. For example, the combined charging system 170 may comprise a European style combined charging system (“CCS2”), Chademo, GBT, or any other emerging aerospace standard charging system, in accordance with various embodiments.

In various embodiments, the charging system 100 includes electrical cables 172. The electrical cables 172 extend from the bi-directional DC/DC converter 120 to a combo plug 174 of the combined charging system 170. The combo plug of the combined charging system 170 is configured to be electrically coupled to a socket of the combined charging system 170. In various embodiments, the combo plug is a component of the charging system 100 and the socket is a component of the electric aircraft 200 or vice versa. The present disclosure is not limited in this regard.

In various embodiments, the bi-directional DC/DC converter 120 is configured to act as an impedance matching device. Additionally, the bi-directional DC/DC converter 120 is configured to allow power to be shuttled to and from the second battery array 210 of the aircraft battery system 201 of the electric aircraft 200, thereby enabling advanced battery state of health (“SOH”) estimation at every charge cycle, in accordance with various embodiments. Thus, each charge cycle may be an opportunity to assess the SOH of each battery module in the second battery array 210 of the aircraft battery system 201 of the electric aircraft 200, which may be utilized to commission each battery module prior to each flight.

In various embodiments, upon a battery module (e.g., ICBM 20 of FIG. 2) within the second battery array 210 reaching the end of its useful life on the electric aircraft 200, the battery module (e.g., ICBM 20 of FIG. 2) may have a secondary life on the charging system 100 as described further herein. In this regard, the second battery array 210 may have more stringent criteria to meet an airworthiness standard than the criteria to which the first battery array 110 is subject for use on the charging system 100. Thus, upon a battery module (e.g., ICBM 20 of FIG. 2) in the second battery array 210 no longer meeting the airworthiness standard, the battery module (e.g., ICBM 20 of FIG. 2) may be transferred to the first battery array 110 of the charging system 100, which may have a lesser criteria for operation (e.g., a lower capacity level or the like) than the second battery array 210.

In various embodiments, a set of battery modules in the first battery array 110 of the charging system 100 may include inventory for electric aircraft 200 (e.g., an electrically powered aircraft). In this regard, newly commissioned battery modules may be disposed in the first battery array 110 and used to facilitate charging of the second battery array 210 of the electric aircraft 200 as an initial use. In response to a battery module (e.g., ICBM 20 of FIG. 2) in the second battery array 210 no longer meeting an airworthiness standard, the battery module disposed in the set of battery modules of the first battery array 110 for inventory purposes may be de-coupled from the first battery array 110 and swapped with the battery module that no longer meets the airworthiness standard. Thus, by having inventory on hand at a respective airport with electric aircraft in accordance with electric aircraft 200, the second battery array 210 can be commissioned for airworthiness prior to every flight and if one of the battery modules does not meet airworthiness, the battery module may be swapped with a battery module used as inventory in the charging system 100, in accordance with various embodiments.

In various embodiments, the control system 130 comprises a supervisory control and data acquisition system (“SCADA”). In this regard, the SCADA system may be configured to monitor and control processes of the charging system 100 from a remote location.

In various embodiments, the monitoring system 140 is in operable communication with a vehicle power distribution system 220 in response to the monitoring system 140 being electrically coupled to the vehicle power distribution system 220 or in response to the electric aircraft 200 becoming in range of a wireless network of the monitoring system. In various embodiments, the monitoring system 140 comprises remote telemetry (i.e., a remote telemetry unit (“RTU”) with a microprocessor-based remote device configured to monitor and report events of the vehicle power distribution system 220). The monitoring system 140 may be configured to communicate with the vehicle power distribution system 220 of the electric aircraft 200 through a wireless or wired connection. In various embodiments, the monitoring system 140 may be configured to transmit any data received during a charging event or the like to external servers for data collection through wireless or wired connections. The present disclosure is not limited in this regard. In various embodiments, the vehicle power distribution system 220 communicates with the monitoring system 140 via a wireless network. In this regard, in response to the vehicle power distribution system 220 becoming in range of the wireless network, the vehicle power distribution system 220 may be configured to transfer information related to operation history of the second battery array 210 to the monitoring system 140. In this regard, battery modules within the second battery array 210 may be continuously monitored for airworthiness, in accordance with various embodiments.

Moreover, charging system 100 (e.g., a mobile charging system), optionally in connection with a remote system, may be configured to charge and/or discharge the first battery array 110 and the second battery array 210 and in connection with that charging and/or discharging, to determine a SOH of each of the first battery array 110, the second battery array 210, and individual battery modules within each array. Thus, the SOH of each module of the first and second battery arrays can be known each time the aircraft is connected to charging system 100, and the desirability of swapping of batteries can be assessed in real-time at each aircraft charging session. In addition, if swapping is indicated as desirable, the swap out module is already located in proximity to the aircraft and its then current SOH is known.

In various embodiments, SOH may be determined by measured methods, predicted methods, or a combination of measured and predicted methods. In various embodiments, the SOH may be determined from a voltage differential measured under a load and used to measure internal impedance. In various embodiments, the SOH may be determined based on measured energy supplied or received during a large depth of discharge cycles. In various embodiments, the SOH may be determined based on a Department of Defense capacity test. The present disclosure is not limited in this regard.

In various embodiments, it may be desirable for battery module (e.g., ICBM 20 of FIG. 2) of the first battery array 110 of the charging system 100 to reduce their wear and tear by restricting max state of charge and min state of charge experienced. In various embodiments, each battery module (e.g., ICBM 20 of FIG. 2) of the second battery array 210 of the electric aircraft 200 may experience a depth of discharge between 40% and 80% for each flight, or between 50% and 70% for each flight.

In various embodiments, each battery module (e.g., ICBM 20 of FIG. 2) of the first battery array 110 of the charging system 100 may go through approximately one cycle per day. In contrast, in accordance with various embodiments, each battery module (e.g., ICBM 20 of FIG. 2) of the second battery array 210 of the electric aircraft may experience multiple cycles a day (e.g., corresponding to a number of flights).

In various embodiments, the vehicle power distribution system 220 is configured to distribute the power from the second battery array 210 to various electrically powered components of the electric aircraft 200 (e.g., an electrical compressor, an electric motor, an electric fan, etc.). In this regard, an electric aircraft 200 may be powered through the vehicle power distribution system 220 utilizing the second battery array 210 of the electric aircraft 200, in accordance with various embodiments. In various embodiments, the vehicle power distribution system 220 is also configured to facilitate charging of the second battery array 210 from the charging system 100.

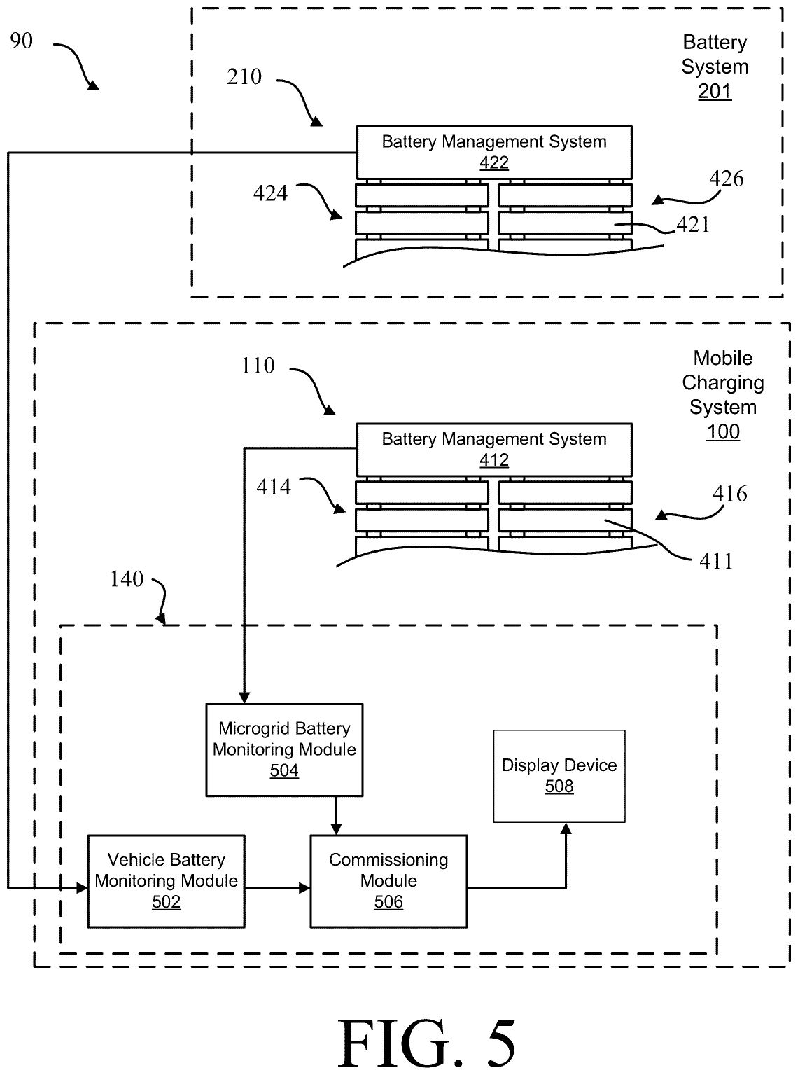

Referring now to FIG. 5, a schematic view of a portion of the electric vehicle charging ecosystem 90 from FIGS. 3 and 4 is illustrated, in accordance with various embodiments. In various embodiments, the first battery array 110 of the charging system 100 comprises a battery management system 412, a first string of battery modules 414 and a second string of battery modules 416. Similarly, the second battery array 210 of the aircraft battery system 201 for the electric aircraft 200 comprises a battery management system 422, a first string of battery modules 424 and a second string of battery modules 426. Although illustrated as comprising a single battery management system and two strings of battery modules for both the first battery array 110 and the second battery array 210, the present disclosure is not limited in this regard. For example, the first battery array 110 may comprise any number of strings of battery modules and/or any number of battery management systems. Similarly, the second battery array 210 may comprise any number of stings of battery modules and/or any number of battery management systems.

The charging system 100 comprises a plurality of battery modules (e.g., ICBMs 20 from FIG. 2) in the first string of battery modules 414 and a plurality of battery modules (e.g., ICBMs 20 from FIG. 2) in the second string of battery modules 416. Similarly, the aircraft battery system 201 comprises a plurality of battery modules (e.g., ICBMs 20 from FIG. 2) in the first string of battery modules 424 and a plurality of battery modules in the second string of battery modules 426 (e.g., ICBMs 20 from FIG. 2). The battery modules of charging system 100 are the same as the battery modules of the aircraft battery system 201. For example, if ICBMs 20 from FIG. 2 are utilized in the charging system 100, ICBMs 20 are also used in aircraft battery system 201. In this regard, battery modules in the first battery array 110 and the second battery array 210 are swappable, or interchangeable, as described further herein. In this regard, a single consistent ICBM may be utilized throughout the electric vehicle charging ecosystem 90. In this regard, the battery modules used in the first battery array 110 and the second battery array 210 have the same physical structure and dimensions, the same connectors, and are operably swappable.

In various embodiments, the charging system 100 may include a first discharge profile and the aircraft battery system 201 may include a second discharge profile. In various embodiments, the second discharge profile the aircraft battery system 201 may comprise a greater discharge rate relative to the first discharge profile of the charging system 100. For example, the second discharge profile may be about three times the first discharge profile or greater, or about five times the first discharge profile or greater, in accordance with various embodiments. In this regard, a greater discharge rate may be desirable for an aircraft system due to impact of weight on aircrafts capabilities.

In various embodiments, the charging system 100 comprises a battery capacity that is greater than an aircraft battery system 201. In various embodiments, a C-rate experienced by the charging system 100 may be less than a C-rate experienced by the aircraft battery system 201.

In various embodiments, the charging system 100 is configured to monitor each ICBM in the second battery array 210 and compare each ICBM to an airworthiness standard. For example, in response to the aircraft battery system 201 being electrically coupled to the monitoring system 140 (i.e., during charging of the electric aircraft 200 from FIG. 3), a vehicle battery monitoring module 502 of the charging system 100 may receive battery data for each ICBM in the second battery array 210 of aircraft battery system 201 via the battery management system 422. In various embodiments, the battery management system 422 is configured to manage a charge rate when the charging system 100 is being charged by an electrical grid.

In various embodiments, the vehicle battery monitoring module 502 may send the battery data for each ICBM in the second battery array 210 to a commissioning module 506. The sent battery data may be real-time data measured during the time when the aircraft is connected to or in proximity of the charging system 100, or the data may be data stored during operation of the aircraft remote from the charging system 100 (e.g. while flying) and sent when later in proximity or connected to the charging system 100. In this regard, the commissioning module 506 compares the battery data to the airworthiness standard. The battery data may include discharge data, shock and vibration data, whether the ICBM was ever over-discharged or over current, etc. The battery data may be tied directly to the airworthiness standard.

Similarly, the charging system 100 is configured to continuously monitor each ICBM in the first battery array 110 and compare each ICBM to an airworthiness standard. For example, the battery management system 412 of the first battery array 110 is continuously in electronic communication with a microgrid battery monitoring module 504 of the charging system 100. In this regard, the microgrid battery monitoring module 504 may receive battery data for each ICBM in the first battery array 110 of charging system 100 via the battery management system 412.

In various embodiments, the vehicle battery monitoring module 502 may send the battery data for each ICBM in the second battery array 210 to a commissioning module 506. In this regard, the commissioning module 506 may classify each ICBM in the first battery array 110 as “swappable” or “non-swappable” based on comparing the battery data to a second airworthiness standard. “Swappable” as referred to herein means capable of replacing an ICBM in the second battery array 210 of the aircraft battery system 201. The second airworthiness standard may be greater than the airworthiness standard for the aircraft battery system 201. In this regard, for an ICBM in the first battery array 110 to be classified as “swappable” the ICBM should meet an initial, or starting, standard for incorporation into an electric aircraft 200 from FIGS. 3 and 4.

The battery data received by the microgrid battery monitoring module 504 may include discharge data, shock and vibration data, whether the ICBM was ever over-discharged or over current, etc. The battery data may be tied directly to the airworthiness standard.

In this regard, when charging an aircraft battery system 201 of an electric aircraft 200 from FIGS. 3 and 4, if an ICBM 421 in the second battery array 210 of the aircraft battery system 201 no longer meets an airworthiness standard, a maintenance person can swap an ICBM 411 in the charging system 100 that is classified as “swappable” by the commissioning module 506, indicating the ICBM 411 meets the second airworthiness standard. Then, the maintenance person can swap out the ICBM 421 with the ICBM 411 in a quick and/or efficient manner. In this regard, the charging system 100 may be configured to provide an on-site inventory management for the aircraft battery system 201, in accordance with various embodiments. Thus, the first battery array 110 of the charging system 100 may include a set of ICBMs that are being utilized for secondary life and/or a set of battery modules that are being utilized initially and act as inventory in case an ICBM of a aircraft battery system 201 for an electric aircraft 200 has to replace an ICBM that no longer meets the airworthiness standard.

In various embodiments, an ICBM 421 in the string of battery modules 424, 426 of the second battery array 210 of the aircraft battery system 201 may be configured for a secondary life with the charging system 100. For example, upon determining that the ICBM 421 no longer meets the airworthiness standard, the ICBM 421 may be disposed in the first battery array 110 charging system 100 and continue to be utilized for charging the aircraft battery system 201. Thus, once an ICBM 421 no longer meets the airworthiness standard, the ICBM may still qualify to be used on the charging system 100, since the ICBM may be significantly less strained during use (i.e., operating a significantly slow discharge profile, not being subject to shock and vibration of an aircraft, etc.).

In various embodiments, an ICBM 411 in the string of battery modules 414, 416 of the first battery array 110 of the charging system 100 may be configured for a primary life in the second battery array 210 of the aircraft battery system 201. For example, to meet an airworthiness standard for the primary life, an ICBM 411 disposed in the first battery array 110 of the charging system 100 may include heightened criteria relative to a standard for use in the second battery array 210 of the aircraft battery system 201, such as having a greater actual capacity relative to a design capacity (i.e., current capacity/design capacity), never experiencing shock and vibrations above a threshold level, never being over-discharged or over current, etc. In this regard, the systems and methods disclosed herein may further sustainability of battery modules and battery systems relative to typical battery modules and systems.

In various embodiments, the commissioning module 506 is in electronic communication with a display device 508. The display device 508 may comprise any suitable hardware, software, and/or database components capable of sending, receiving, and storing data. For example, display device 508 may comprise a personal computer, personal digital assistant, cellular phone, smartphone (e.g., IPHONE®, BLACKBERRY®, and/or the like), IoT device, kiosk, and/or the like. Display device 508 may comprise an operating system, such as, for example, a WINDOWS® mobile operating system, an ANDROID® operating system, APPLE® IOS®, a BLACKBERRY® operating system, a LINUX® operating system, and the like. Display device 508 may also comprise software components installed on display device 508 and configured to enable access to various components of monitoring system 140. For example, display device 508 may comprise a web browser (e.g., MICROSOFT INTERNET EXPLORER®, GOOGLE CHROME®, etc.), an application, a micro-app or mobile application, or the like, configured to allow the display device 508 to access and interact with monitoring system 140 (e.g., directly or via a respective UI, as discussed further herein). Thus, a status of each ICBM in the first battery array 110 and the second battery array 210 of the aircraft battery system 201 being charged may be checked and/or verified prior to the electric aircraft 200 from FIGS. 3 and 4 taking off. If an ICBM in the second battery array 210 no longer meets the airworthiness standard, an ICBM from the first battery array 110 that does may be swapped out with the ICBM that no longer meets the airworthiness standard.

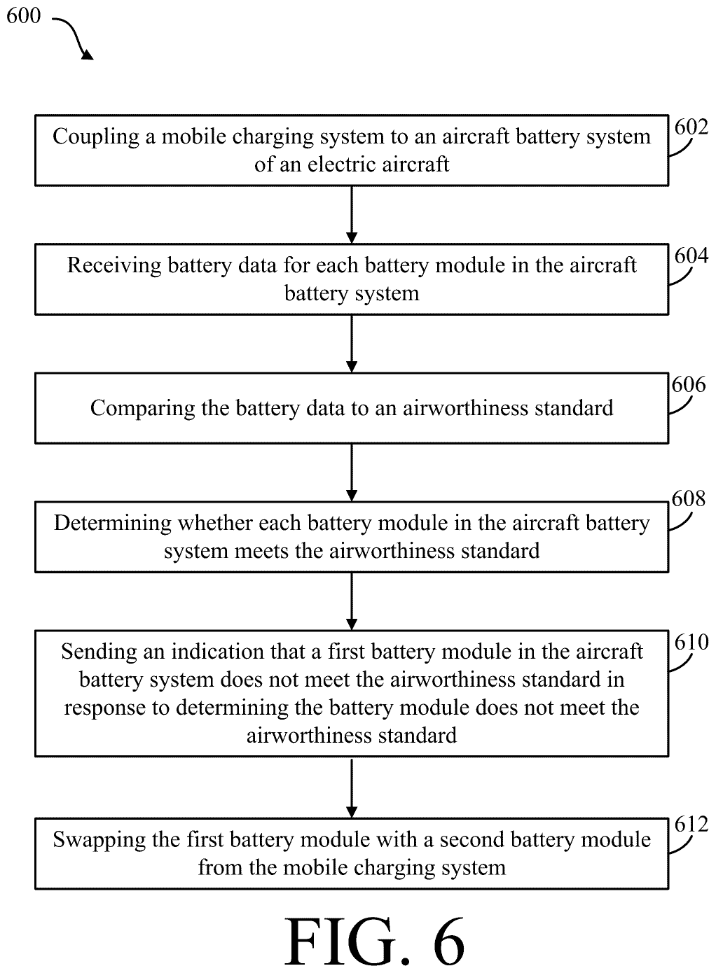

Referring now to FIG. 6, a method 600 for maintaining an aircraft battery system for an electric aircraft is illustrated, in accordance with various embodiments. The method 600 comprises coupling a charging system (e.g., a mobile charging system) to an aircraft battery system of an electric aircraft (step 602). A monitoring system of the charging system may be coupled to a battery management system of the electric aircraft in response to coupling the charging system to the aircraft battery system. In this regard, battery data may be sent from the battery management system of the electric aircraft to the monitoring system.

The method 600 further comprises receiving, via a processor of the monitoring system, the battery data for each battery module in the aircraft battery system (step 604). The battery data may include discharge data, shock and vibration data, whether the ICBM was ever over-discharged or over current, etc.

The method 600 further comprises comparing, via the processor, the battery data, and/or data derived therefrom, to an airworthiness standard (step 606). The airworthiness standard may be defined based on discharge data, a time of use, shock and vibration data, a battery capacity threshold, or the like. The capacity threshold may comprise a percentage of rated capacity; absolute capacity (e.g., 1 kWh) or the like. In various embodiments, the airworthiness standard may include mechanical limits (e.g., wear and tear thresholds, or any other limits imposed by certification testing, such as RTCA/DO-160G testing or the like). In various embodiments, the aircraft battery system 201 of the electric aircraft 200 may include an available power threshold. In response to the aircraft battery system 201 no longer having a potential power supply meeting or exceeding the available power threshold, a battery module in the aircraft battery system 201 with a minimum power capability, when compared to the other battery modules in the aircraft battery system 201, may be swapped with a fully capable battery module in the charging system 100, in accordance with various embodiments. The airworthiness standard may further be defined by one of: a number of flight cycles of the battery modules in the aircraft battery system have been used, a number of hours the battery modules in the aircraft battery system have been used, or the like.

The method 600 further comprises determining whether each battery module in the aircraft battery system meets the airworthiness standard (step 608). In various embodiments, in response to determining a first battery module in the aircraft battery system does not meet the airworthiness standard, the processor may send an indication that the first battery module does not meet the airworthiness standard (step 610). In this regard, a maintenance indication or the like may be provided to a display device of the charging system, in accordance with various embodiments.

The method may further comprise determining whether a battery module on the charging system meets the airworthiness standard, and suggesting a specific battery module from the charging system for swapping to the aircraft battery system for replacing the battery module in the aircraft battery system that does not meet the airworthiness standard.

The method 600 further comprises swapping the first battery module with a second battery module from the charging system (step 612). Prior to swapping the first battery module and the second battery module, a maintenance person may verify the second battery module meets the airworthiness standard by checking a status of the second battery module via the display device. In this regard, the monitoring system may be configured to continuously monitor all battery modules in the charging system as described previously herein.

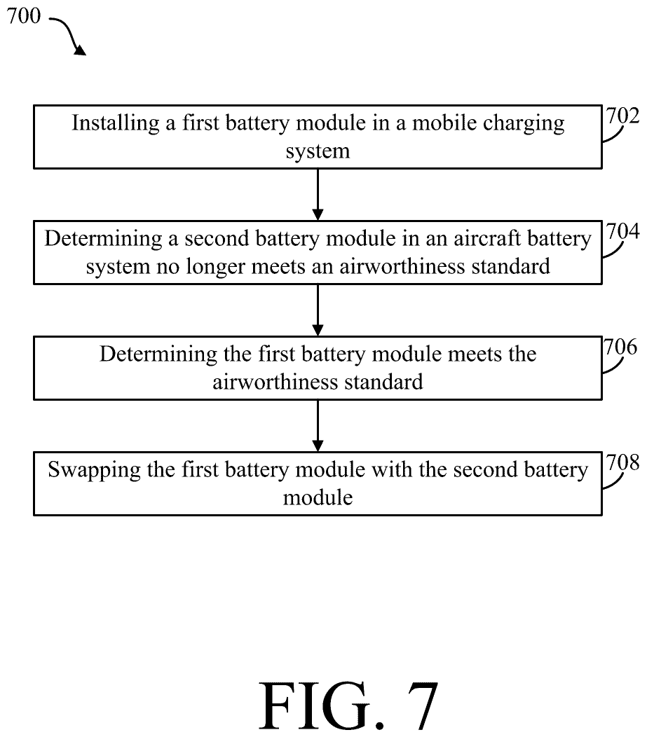

Referring now to FIG. 7, a method 700 of inventory management for an aircraft battery system is illustrated, in accordance with various embodiments. The method 700 comprises installing a first battery module in a charging system (step 702). The first battery module may be installed with an intent of being inventory in case a battery module of an electric aircraft no longer meets an airworthiness standard as described herein. In this regard, a set of battery modules in the charging system may act as inventory for maintenance of an aircraft battery system of the electric aircraft.

The method 700 further comprises determining a second battery module in the aircraft battery system no longer meets an airworthiness standard (step 704). Step 704 may be determined from a monitoring system of the charging system. The monitoring system may receive the data and perform the comparison in response to being electrically coupled to a battery management system of the aircraft battery system as described previously herein.

The method 700 further comprises determining the first battery module meets the airworthiness standard (step 706). Each battery module in the set of battery modules in the charging system are continuously monitored for airworthiness as described previously herein. In this regard, a list of airworthy batteries may be created and stored in the monitoring system as described previously herein.

The method 700 further comprises swapping the first battery module with the second battery module (step 708). In this regard, the first battery module may be installed in the battery system of the charging system and the second battery module may be installed in the aircraft battery system. Thus, the second battery module may receive a secondary life in the charging system, and the first battery module may be utilized in accordance with a primary intent for the second battery module, in accordance with various embodiments. In various embodiments, the first battery module may then be transferred back to the charging system after the first battery module no longer meets an airworthiness standard.

While the principles of this disclosure have been shown in various embodiments, many modifications of structure, arrangements, proportions, elements, materials and components (which are particularly adapted for a specific environment and operating requirements) may be used without departing from the principles and scope of this disclosure. These and other changes or modifications are intended to be included within the scope of the present disclosure and may be expressed in the following claims.

The present disclosure has been described with reference to various embodiments. However, one of ordinary skill in the art appreciates that various modifications and changes can be made without departing from the scope of the present disclosure. Accordingly, the specification is to be regarded in an illustrative rather than a restrictive sense, and all such modifications are intended to be included within the scope of the present disclosure. Likewise, benefits, other advantages, and solutions to problems have been described above regarding various embodiments.

However, benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

When language similar to “at least one of A, B, or C” or “at least one of A, B, and C” is used in the claims or specification, the phrase is intended to mean any of the following: (1) at least one of A; (2) at least one of B; (3) at least one of C; (4) at least one of A and at least one of B; (5) at least one of B and at least one of C; (6) at least one of A and at least one of C; or (7) at least one of A, at least one of B, and at least one of C.

We claim:

1. A microgrid charging system, comprising:
a battery system comprising a first plurality of battery modules;
a battery management system including a controller in operable communication with the first plurality of battery modules, the controller operable to:
receive battery data for each of the first plurality of battery modules including at least one of a discharge frequency, shock and vibration data, battery capacity data;
compare the battery data for each of the first plurality of battery modules to an airworthiness standard; and
determine whether each of the first plurality of battery modules is airworthy based on the airworthiness standard.

2. The microgrid charging system of claim 1, wherein the microgrid charging system is configured to charge an aircraft battery system.

3. The microgrid charging system of claim 2, wherein each of the first plurality of battery modules are cross compatible with each of a second plurality of battery modules in the aircraft battery system.

4. The microgrid charging system of claim 3, further comprising an aircraft battery management system configured to operably couple to the battery management system of the microgrid charging system.

5. The microgrid charging system of claim 4, further comprising an aircraft battery monitoring system including a second controller operable to:
receive, from the aircraft battery management system, the battery data for the second plurality of battery modules in the aircraft battery system in response to electrically coupling the aircraft battery management system to the battery system for charging; and
determine whether one of the second plurality of battery modules no longer meets the airworthiness standard.

6. The microgrid charging system of claim 2, wherein:
the aircraft battery system comprises a second plurality of battery modules, and
a first battery module in the first plurality of battery modules is cross compatible with a second battery module in the second plurality of battery modules.

7. The microgrid charging system of claim 2, wherein the controller is further operable to send an airworthiness status for each battery module in the first plurality of battery modules to a display device in response to coupling the battery management system to an onboard battery management system of the aircraft battery system.

8. A battery ecosystem, comprising:
the microgrid charging system of claim 1, the microgrid charging system including a first discharge profile;
an aircraft propulsion battery system comprising a second plurality of battery modules, the aircraft propulsion battery system including a second discharge profile, wherein:
a first battery module in the first plurality of battery modules is identical to a second battery module in the second plurality of battery modules,
the first battery module is adaptable to replace the second battery module, and
the second battery module is adaptable to replace the first battery module.

9. The battery ecosystem of claim 8, wherein the second discharge profile being at least five times greater than the first discharge profile.

10. The battery ecosystem of claim 8, further comprising an airworthiness commissioning module configured to determine an airworthiness status for each of the first plurality of battery modules and the second plurality of battery modules.

11. The battery ecosystem of claim 10, wherein the first battery module in the first plurality of battery modules is configured to replace the second battery module in the second plurality of battery modules in response to the first battery module having a first airworthiness status that is airworthy and the second battery module having a second airworthiness status that is non-airworthy, and wherein the second battery module in the second plurality of battery modules is configured to replace the first battery module in the first plurality of battery modules.

12. The battery ecosystem of claim 10, wherein:
the aircraft propulsion battery system includes an aircraft battery management system, and
the aircraft battery management system is configured to operably couple to an aircraft battery monitoring system of the microgrid charging system.

13. The battery ecosystem of claim 12, wherein the microgrid charging system further comprises a microgrid monitoring system configured to monitor the first plurality of battery modules.

14. The battery ecosystem of claim 13, further comprising a vehicle battery monitoring system and a commissioning module, the vehicle battery monitoring system and the microgrid monitoring system in operable communication with the commissioning module.

15. A method, comprising:
installing a first battery module in a microgrid charging system, the microgrid charging system configured to charge an aircraft propulsion battery system;
determining a second battery module in the aircraft propulsion battery system no longer meets an airworthiness standard;
determining the first battery module is airworthy based on the airworthiness standard; and
swapping the first battery module with the second battery module.

16. The method of claim 15, further comprising replacing the second battery module with the first battery module.

17. The method of claim 15, wherein determining whether the first battery module is airworthy based on the airworthiness standard further comprises comparing at least one of:
a battery capacity of the second battery module to a threshold battery capacity;
a number of flight cycles of the second battery module to a threshold number of flight cycles; and
a number of hours of the second battery module to a threshold number of hours.

18. A method comprising:
receiving, via a processor and through a microgrid monitoring system, an airworthiness status of each battery module in a first plurality of battery modules in a microgrid battery system;
receiving, via the processor and through an aircraft battery monitoring system, the airworthiness status of each of a second plurality of battery modules in an aircraft battery system; and
determining, via the processor, a first battery module in the first plurality of battery modules to replace a second battery module in the second plurality of battery modules in response to the second battery module having a first airworthiness status that is non-airworthy and the first battery module having a second airworthiness status that is airworthy.

19. The method of claim 18, further comprising determining via the processor, the second battery module can replace the first battery module in the microgrid battery system.

20. The method of claim 18, wherein the airworthiness status is determined by comparing at least one of:
a battery capacity of the second battery module to a threshold battery capacity;
a number of flight cycles of the second battery module to a threshold number of flight cycles; and
a number of hours of the second battery module to a threshold number of hours.
